(19) United States
(12) Patent Application Publication
(10) Pub. No.: US 2024/0297480 A1
(43) Pub. Date: Sep. 5, 2024

(54) BICHROMATIC LASER FREQUENCY STABILIZATION SYSTEM AND METHOD BASED ON DIFFERENTIAL DETECTION OF COEXISTING LAMB-DIPS AND LAMB-PEAKS WITH MULTIPLE INTERACTIONS

(71) Applicant: National Time Service Center (NTSC), Chinese Academy of Science (CAS), Xi'an (CN)

(72) Inventors: Shougang ZHANG, Xi'an (CN); Tenghui YANG, Xi'an (CN); Enxue Yun, Xi'an (CN); Qiang HAO, Xi'an (CN); Guobin LIU, Xi'an (CN); Yuping GAO, Xi'an (CN)

(73) Assignee: National Time Service Center (NTSC), Chinese Academy of Science (CAS), Xi'an (CN)

(21) Appl. No.: 18/447,624

(22) Filed: Aug. 10, 2023

(30) Foreign Application Priority Data
Mar. 5, 2023 (CN) 202310201210.6

(51) Int. Cl. H01S 5/0687; H01S 3/094; H01S 3/109; H01S 5/00; H01S 5/04; H01S 5/10

(52) U.S. Cl. CPC H01S 5/0687; H01S 3/094076; H01S 3/1095; H01S 5/0071; H01S 5/041; H01S 5/1092

(57) ABSTRACT

Provided are a method and a system for bichromatic laser frequency stabilization based on differential detection of coexisting Lamb-dips and Lamb-peaks under multiple interactions. Based on multiple interactions between a multichromatic laser beam and a quantum resonance system in a Doppler-free configuration, and by setting the relative polarization directions and Raman phases between the pump and probe light which propagate in opposite directions and overlap in space, Lamb-dips and Lamb-peaks signals are generated; and by subtracting one from the other, a Doppler-free quantum resonance signal with high rejection of Doppler-broadening background and common-mode noise is obtained. The Doppler-free quantum resonance signal obtained in the present application has improved contrast and signal-to-noise ratio, and maintained narrow linewidth, making it applicable for precision spectral measurement as well as for laser frequency locking.

### CROSS-REFERENCE TO RELATED APPLICATIONS

This application claims priority to Chinese Patent Application No. 202310201210.6, filed on Mar. 5, 2023, the content of which is incorporated herein by reference in its entirety.

### TECHNICAL FIELD

The present application relates to quantum frequency standard, precision spectroscopy, and other technologies in the precision measurement physics, in particular to a differential detection technique in which Lamb-dips and Lamb-peaks coexist.

### BACKGROUND

Lasers, especially semiconductor lasers, generally have a free-running linewidth above MHz level and their frequency fluctuates greatly due to factors like temperature and driving current, which will limit the performance and application scope of laser-based precision measurement systems. The linewidth of a laser can usually be narrowed by using an external cavity. Take an external cavity diode laser (ECDL) based on Littrow or Littman configuration as an example. Its frequency fluctuation can be suppressed through laser frequency stabilization technologies, that is, the laser frequency can be locked to a more stable reference frequency. For example, it can be locked to the transmission peak center of a high-Q Fabry-Pérot cavity (F-P cavity) or locked to a transition spectral line of a highly stable quantum system.

At present, a laser beam with ultra-narrow linewidth (below the Hz level) can be obtained by laser frequency stabilization method using a F-P cavity, but there is the frequency drift problem over time, and due to its large size, vibration sensitivity as well as high cost, the F-P cavity is not suitable in miniaturized applications. Laser frequency stabilization using a quantum resonance system can solve the above problems, and the commonly used methods are saturated absorption spectra (SAS), polarization spectroscopy, modulation transfer spectroscopy (MTS), dichroic atomic vapour laser lock (DAVLL), etc. They lock the laser frequency to the narrow-linewidth resonance signal of the quantum resonance system.

Among them, the dichroic atomic vapour laser lock (DAVLL) technique requires a strong external magnetic field, and the signals pass through the quantum resonance system in a single direction, resulting in Doppler broadening in the linewidth of the resonance signal, which is not conducive to achieving high-stability laser frequency stabilization. The saturated absorption spectra (SAS) technique requires not only a pump light and a probe light that propagate in opposite directions and overlap in space but also a spatially separated reference light beam. Therefore, the optical apparatus is complex and it is hard to realize miniaturization with chip-scale atomic vapor cells. The signal-to-noise ratio (SNR) of the frequency discrimination signal obtained by the polarization spectroscopy technique is generally higher than that in SAS, but there is the problem of zero drift, which results in the slow drift of the laser frequency. With a very high SNR in its frequency discrimination signal, modulation transfer spectroscopy (MTS) is now the mainstream method for high-performance laser frequency stabilization. However, due to the need for separate frequency or phase modulation to pump light, which is usually achieved by external modulators with large volume and power consumption, such as electro-optic modulator (EOM) or acoustic-optic modulator (AOM), the application of MTS in miniaturization case is limited.

The spectral signal obtained by the existing mainstream laser frequency stabilization method cannot be completely free of Doppler broadening background signals. Though it is possible to obtain a Doppler-free error signal by means of synchronous modulation and demodulation for laser frequency stabilization, it is insufficient for precision measurement of the spectrum, because when the Doppler-free error signal is obtained by modulation and demodulation techniques to measure the resonance transition frequency of the quantum resonance system, the zero crossing point of the error signal and its drift are closely related to the modulation and demodulation parameters, as well as the residual amplitude modulation (RAM), and as a result, the measurement error is generated. In addition, for frequency stabilization methods using light intensity detection, such as modulation transfer spectroscopy (MTS), there are considerable noises like laser intensity noise to detection amplitude noise (AM-AM noise), detection amplitude noise also may arise from laser frequency jitter by absorption lines (FM-AM noise), and detector noise, which limits the further improvement of frequency stability in laser frequency stabilization systems.

### SUMMARY

In view of the foregoing deficiencies in the prior art, the present application provides a method and a system for bichromatic laser frequency stabilization based on differential detection of Lamb-dips and Lamb-peaks under multiple interactions, through which the differential signal obtained is free of Doppler-broadening background, and can be used for precision spectral measurement and laser frequency locking, to obtain a laser frequency stabilization system with ultra-low frequency noise and compact size.

A technical scheme adopted in the present application to solve the technical problem includes: a bichromatic laser frequency stabilization method based on differential detection of coexisting Lamb-dips and Lamb-peaks, comprising: 1, providing a multichromatic laser beam that has multiple interactions with a quantum resonance system in a Doppler-free configuration; 2, setting the relative polarization directions and Raman phases of the pump and probe light which propagate in opposite directions and overlap in space to obtain a resonance signal with coexisting Lamb-dips (absorption decreased) and Lamb-peaks (absorption enhanced); and 3, subtracting the Lamb-peaks signal from the Lamb-dips signal to obtain Doppler-free quantum resonance signal, in specific comprising the steps:
1) providing a multichromatic laser beam having frequency f₁ and frequency f₂ with frequency difference close to the two ground states interval;
2) the laser beam having multiple interactions with a quantum resonance system in a Doppler-free configuration, that is, the laser beam is split into a pump light and a probe light which propagate in opposite directions and overlap in space and act on the quantum resonance system simultaneously;
3) setting the relative polarization directions of the pump and probe light using wave plates, and setting the relative Raman phases between the pump and probe light by means of mirrors. This allow the dark state created by the pump light and the two dark states created by the two orthogonal polarization components of the probe light to have constructive interference and destructive interference respectively, then coexisting Lamb-dips and Lamb-peaks are generated;
4) separating and detecting the orthogonal polarization components of the probe transmitted light after its interactions with the quantum resonance system, the Lamb-dip signal and Lamb-peak signal are then obtained simultaneously;
5) subtracting the Lamb-peak signal from Lamb-dip signal to generate a differential signal.

In step 4), two detection ports of a balanced detector are used to detect the orthogonal polarization components of the transmitted light which is separated spatially and polarized.

In step 5), the differential output port of the balanced detector is used to calculate the difference between the Lamb-dip signal and the Lamb-peak signal to obtain a differential signal.

The quantum resonance system can be based on H, Li, Na, K, Rb, Cs, Be, Mg, Ca, Sr, Ba, He, Ne, Ar, Kr, and Xe.

The application further provides a bichromatic laser frequency stabilization system based on differential detection of coexisting Lamb-dips and Lamb-peaks, comprising a multichromatic laser system, high reflectivity devices, a quantum resonance system, a polarization conversion and separation device, and a detection device. The multichromatic laser system generates a dual-frequency laser beam which then, acting as a pump light has multiple interactions with the quantum resonance system in the Doppler-free configuration under the action of the high reflectivity devices. Under the actions of a wave plate and a mirror, the transmitted light from the pump light is converted to a probe light which is counterpropagating and overlapping with the pump light. The probe light is polarized at a certain angle relative to the pump light. The probe light enters the quantum resonance system and interacts with the quantum resonance system to have Lamb-dips and Lamb-peaks respectively. Through the polarization conversion and separation device, a Lamb-dip signal and a Lamb-peak signal are obtained, and the detection device output the differential signal of Lamb-dip and a-peak signal for locking the laser frequency.

In one preferred embodiment, the microwave signal generated by a microwave source of the multichromatic laser system and the current supplied by a DC source are connected to the microwave port and the DC port of a Bias-Tee respectively to drive a semiconductor laser to generate a bichromatic laser beam which then passes through a non-polarizing beam splitter and enters a quantum resonance system as a pump light. The high reflectivity devices are provided with a pair of mirrors which are arranged at two sides of the quantum resonance system. The pump light enters the quantum resonance system repeatedly under the action of the mirrors to increase the effective optical path length for interaction. A probe light that is counterpropagating and overlapping with the pump light and polarized at a certain angle is obtained from the transmitted light from the pump light through a quarter-wave plate and a mirror. The probe light then enters the quantum resonance system and interacts with the system, and the two orthogonal polarization components of the probe light, i.e., the parallel and vertical polarization component, interact with the quantum resonance system and produce Lamb-dips and Lamb-peaks respectively. The transmitted portion of the probe light is separated from the counterpropagating and overlapping pump light through the non-polarizing beam splitter, then passes through a quarter-wave plate and a half-wave plate, and separated by a polarizing beam splitter. The parallel polarization component is detected by the detection device to obtain a Lamb-dip resonance signal, and the vertical polarization component is detected by the detection device to obtain a Lamb-peak resonance signal. Finally, a differential signal is obtained.

In another preferred embodiment, the high reflectivity device is replaced by F-P cavity consisting of two cavity mirrors arranged face to face at two sides of the quantum resonance system.

In yet another preferred embodiment, instead, the probe light is obtained from a non-polarizing beam splitter and is configured to be at an angle with the polarization direction of the pump light through the adjustment of a half-wave plate.

In still another preferred embodiment, the spatial positions of the pump light and the probe light are exchanged, and polarization conversion and differential detection are postponed to be behind the beam splitter. After passing through an electro-optic modulator, the pump light enters a quantum resonance system and interacts with it multiple times, during which four-wave mixing and modulation transfer occur, making the probe light interacting with the quantum resonance system contain a modulated signal, and a frequency discrimination signal can be obtained through synchronous demodulation techniques to stabilize the laser frequency.

The beneficial effects of the application are as follows.

1. With this interaction configuration, in which the pump light and the probe light propagate in opposite directions and overlap in space, the simultaneous Lamb-dips and Lamb-peaks are generated by setting the relative polarization directions and the Raman phases of the pump and probe light; with separating and detecting the orthogonal polarization components of the probe transmitted light, the Lamb-dip signal and Lamb-peak signal are then obtained simultaneously; both of which show the same Doppler-broadened background, while the former show a Doppler-free transmitted peak, the latter is transmitted valley.

2. A differential signal is obtained by subtracting the Lamb-peak signal from Lamb-dip signal, thus the Doppler-broadened background is almost suppressed, retaining only a Doppler-free quantum resonance signal with a linewidth that is close to natural linewidth with proper light power. The amplitude of the differential signal is increased compared with the Lamb-dip signal and the Lamb-peak signal, and the common-mode noise of the system is highly suppressed, thus the SNR of the Doppler-free quantum resonance signal is greatly improved, it can be applied for precision spectral measurement as well as for laser frequency stabilization, thus realizing a compact laser source with ultra-low frequency noise.

3. The locking of a monochromatic or bichromatic laser beam can be realized by adopting a flexible frequency locking method, the bichromatic laser beam can be generated with direct-modulation a semiconductor laser, which is compacter, less power consumption, and more robust than an external modulator, e.g., electro-optic modulator, acousto-optic modulator, etc. When a frequency discrimination signal (error signal) is desired, a low frequency (below MHz level) modulation signal can be coupled to the laser drive current, the frequency discrimination signal is obtained by well-established synchronous modulation and demodulation technology, which greatly reduces the size and power consumption of the frequency stabilization system and improves its robustness.

4. The application has good compatibility and can be combined with other spectroscopic technologies like modulation transfer spectroscopy and polarization spectroscopy, thus leads to an even higher SNR resonance signal, and implements an ultra-high performance laser frequency stabilization system.

### BRIEF DESCRIPTION OF THE DRAWINGS

FIG. 1 is a schematic diagram that illustrates the principle of the present application.

FIGS. 2(a)-2(d) are schematic diagrams showing the devices in accordance with the four embodiments of the present application.

FIG. 3 is a schematic diagram showing the involved energy level of quantum resonance system configurations and the corresponding laser fields of the present application, wherein (a) is a degenerate two-level system and the corresponding laser field, and (b) is a 3-level system and the corresponding laser fields.

FIG. 4 is a plot of simultaneous Lamb-dips signal (solid curve) and Lamb-peaks signal (dashed curve) observed with the scheme of FIG. 2(a) in the present application, in which the bichromatic pump and probe light interact with ⁸⁷Rb atomic ensemble in a vapor cell with single-pass, the resonance signals from left to right corresponding to |5²S_{1/2}, F=1&2 [symbol] →|5²P_{1/2}, F′=1 [symbol] , |5²S_{1/2}, F=1&2 [symbol] →|5²P_{1/2}, F′=2 [symbol] , respectively, the central is their crossover signal.

FIG. 5 is a plot of simultaneous Lamb-dips signal (solid curve) and Lamb-peaks signal (dashed curve) observed with multiple interactions between the bichromatic pump and probe light and ⁸⁷Rb atomic ensemble in the vapor cell, the corresponding transitions of the resonance signals are the same as the FIG. 4.

FIG. 6 is a plot of Doppler-free differential signals of Lamb-dips signal and Lamb-peaks signal obtained from single interaction (gray curve) and multiple interactions (black curve), the corresponding transitions of the resonance signals are the same as the FIG. 4.

FIG. 7 is a plot of observed contrasts of PD1 (C_PD1), PD2 (C_PD2) and their difference (C_PD1−C_PD2) as function of relative polarization angle between the linear polarized bichromatic pump and probe light in the single light-atom interaction scheme. The transition is |5²S_{1/2}, F=1&2 [symbol] →|5²P_{1/2}, F′=1 [symbol] of ⁸⁷Rb. Here the contrast (C) of the resonance is defined as the ratio between the Lamb-dip (Lamb-peak) signal amplitude and the dc background level in the bottom (top) of the sub-Doppler resonance.

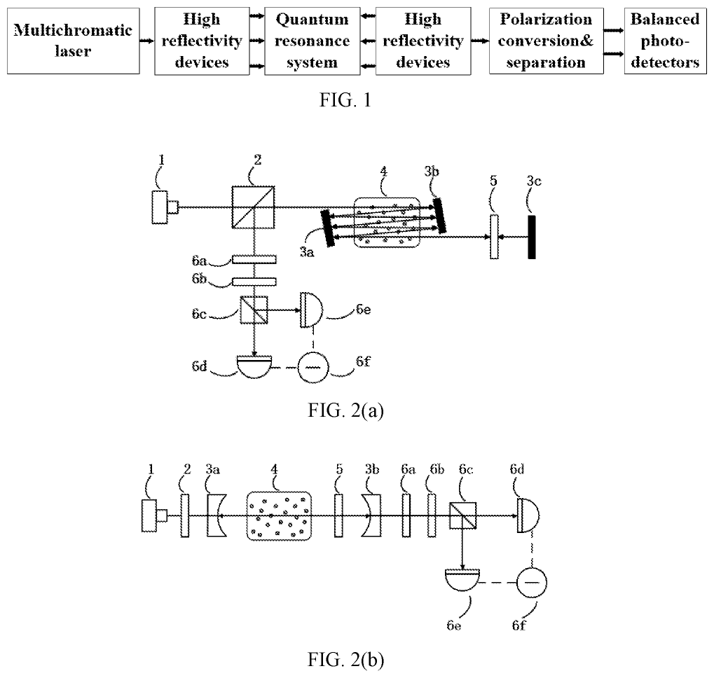

### DETAILED DESCRIPTION OF THE EMBODIMENTS

The present application is further described below with reference to the attached drawings and examples, and the application is not limited to the examples shown and described herein.

The quantum resonance system of the present application can be based on H, Li, Na, K, Rb, Cs, Be, Mg, Ca, Sr, Ba, He, Ne, Ar, Kr, and Xe. A laser frequency stabilization device realized by the interaction between laser beams and ⁸⁷Rb atoms is taken as an example to describe the specific embodiment of the present application, and the present application is not limited to this configuration and covers all the foregoing configurations.

The present application comprises a multichromatic laser system, high reflectivity devices, a quantum resonance system, a polarization conversion and separation device, and a detection device. The multichromatic laser system generates a bichromatic laser beam containing frequency components of f₁ and f₂. The bichromatic laser beam interacts with the quantum resonance system with multiple-pass in a Doppler-free configuration. After the interactions, the probe transmitted light is separated in spatial from pump light, and its orthogonal polarization components are separated to obtain a Lamb-dip signal and a Lamb-peak signal, and finally a differential signal is obtained through the differential channels of balanced detectors.

A differential detection method based on multiple interactions provided in the application includes the following steps: first, a bichromatic laser beam having frequency components f₁ and f₂ is generated; in a Doppler-free configuration, the laser beam is split into a pump light and a probe light which are counterpropagating and overlapping, and interacts with a quantum resonance system by multiple-pass; wave plates are used to set the relative polarization directions of the pump and probe light; and mirrors are used to set the relative Raman phases of the two, so as to enable the dark state created by the pump light and two dark states created by two orthogonal polarization components of the probe light to have constructive interference and destructive interference respectively, thus to obtain an interaction configuration with coexisting Lamb-dips and Lamb-peaks; the orthogonal polarization components of the probe transmitted light is separated spatially and detected by balanced detectors, respectively, a Lamb-dip signal and a Lamb-peak signal are then obtained simultaneously; using the differential output ports of the balanced detectors, a differential signal is obtained by subtracting the Lamb-peak signal from the Lamb-dip signal. The differential signal is free of Doppler-broadened background compared with the Lamb-dip signal and Lamb-peak signal, only retains the Doppler-free quantum resonance signal with narrower linewidth. The amplitude of the Doppler-free resonance signal is increased, and the common-mode noise of the system is highly suppressed.

The coexisting Lamb-dips and Lamb-peaks in the configuration of the present application can be decomposed into incoherent and coherent interaction processes, wherein, the incoherent interaction process mainly includes:

A, a saturated absorption process. The pump light and the probe light which are counter-propagating and spatially overlapped pass through the atomic system. According to the Doppler effect, only atoms with zero velocity components on the probe light path have zero Doppler shift and interact with the pump light and probe light at the same time. Because the excitation rate of absorption transition of these atoms is increased by relatively strong pump light to be comparable with the relaxation rate, the ground state population is significantly reduced, so the absorption of the probe light is reduced, thus forming Lamb dips with Doppler-free linewidth.

B, optical pumping of the atomic population between Zeeman levels of ground state. In the configuration of the application, the pump light pump atoms population toward higher |m_{F}| sublevels, and the counterpropagating probe light absorption is enhanced to form Lamb peaks.

C, optical pumping of the atomic population between hyperfine levels of ground state. In the configuration of the present application, optical pumping can prevent atoms from leaking to one single hyperfine level of the ground state, so that more atoms can participate in the interaction of bichromatic light, thus increase the Lamb-dip signal and the Lamb-peak signal.

In the configuration, the coherent action is a process in which the dark state created by the pump light will constructive interference or destructive interference with the two dark states created by the two orthogonal polarization components of the probe light, thus form simultaneous electromagnetically induced transparency and absorption (EIT and EIA), which would contribute the Lamb-dip and -peak signal respectively. The constructive or destructive interference of dark states between the pump and probe light can be adjusted by the relative polarization directions of the pump and probe light, as well as the relative Raman phase between the pump and probe light, which can be adjusted by the position of the mirrors.

Four differential detection systems which can realize coexisting Lamb-dips and Lamb-peaks under multiple interactions are provided in the present application.

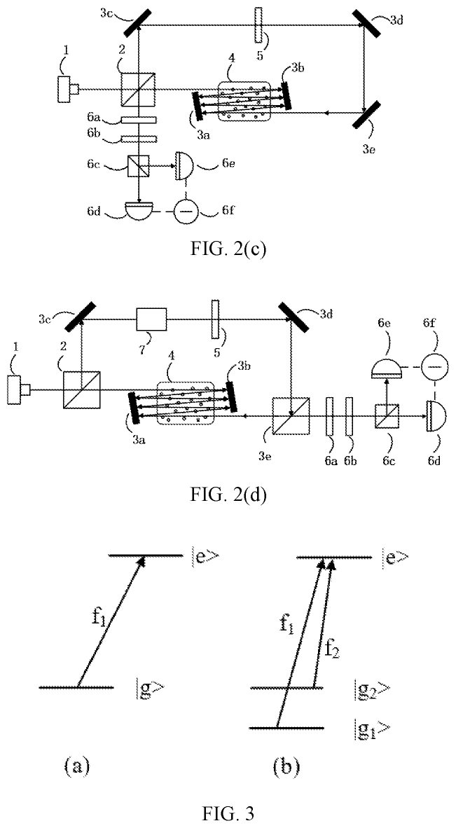

FIG. 2(a) shows a first system configuration of the present application. Firstly, the bichromatic light source can be generated with direct-modulation a semiconductor laser 1, wherein the microwave frequency used for the modulation is v_{hf}/n, v_{hf} for the two ground states frequency splitting, n for a positive integer. The application takes the half-wave modulation for example, in which the bichromatic light is generated by the direct modulation of a high modulation bandwidth laser diode with microwave frequency around v_{hf}/2. The bichromatic light beam passes through a non-polarizing beam splitter 2, then it serves as a pump light to interact with ⁸⁷Rb atoms quantum resonance system 4, the multiple-pass interactions are realized by a pair of high-reflectivity mirrors 3a, 3b to increase the effective optical path length, thereby obtaining a quantum resonance signal with higher contrast and SNR. Then, the transmitted light of the pump light is reflected by a mirror 3c to obtain a counter-propagated and overlapped probe light. Due to the double-pass of a quarter-wave plate 5, the linear polarized probe beam with a certain angle θ relative to the pump beam is generated. The probe light enters the quantum resonance system and interacts with it, that is, the two orthogonal polarization components of the probe light, namely the parallel and vertical polarization components, interact with the quantum resonance system and produce Lamb-dips and Lamb-peaks respectively. The transmitted light of the probe light is separated spatially from the counter-propagated pump light by the non-polarizing beam splitter 2, and then its polarization is separated by a quarter-wave plate 6a, a half-wave plate 6b and a polarizing beam splitter 6c, with the parallel polarization component being detected by a detector 6d to obtain a Lamb-dip resonance signal for instance, and the vertical polarization component being detected by a detector 6e to obtain a Lamb-peak resonance signal. Finally, a differential signal is obtained with an electronic subtracter 6f at the differential ports of the balanced detectors.

Different from the traditional Doppler-free configurations and its Lamb-dip signal, the resonance signals in the configuration of the present application have several features:
1) the Lamp-dip and Lamp-peak signals are obtained simultaneously by detecting the parallel and vertical polarization components of the probe light;
2) the Lamp-dip and Lamp-peak signals show the same Doppler-broadened background, while the Doppler-free signals are reversed, the former show a Doppler-free transmitted peak, the latter is transmitted valley.

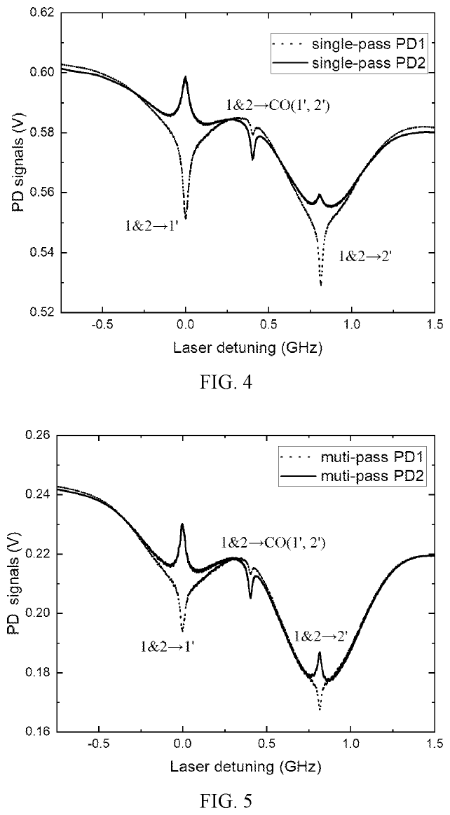

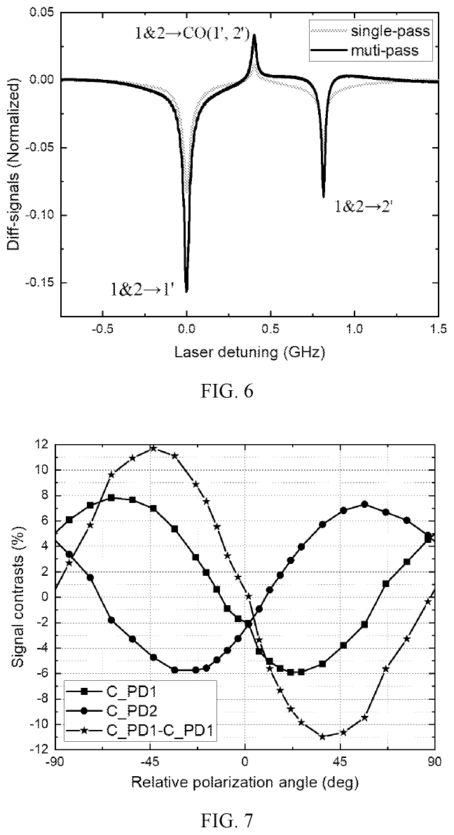

The bichromatic pump and probe light interact with ⁸⁷Rb atomic ensemble in vapor cell by single-pass (or multiple-pass) to obtain Lamp-dips and Lamp-peaks at the same time, as shown in FIG. 4 and FIG. 5, where the transition spectral lines in FIG. 4 correspond to each other from left to right: |5²S_{1/2}, F=1&2 [symbol] →|5²P_{1/2}, F′=1 [symbol] , |5²S_{1/2}, F=1&2 [symbol] →|5²P_{1/2}, F′=2 [symbol] , with their cross-over resonance signals in the middle, and the spectral line transitions in FIG. 5 are the same as those in FIG. 4. By finely tuning the quarter-wave plate 6a and the half-wave plate 6b, the Doppler-broadening background signals of the Lamb-dip signal and the Lamb-peak signal can be the same, and the differential signal is obtained with the electronic subtractor 6f at the differential ports of the balanced detectors, as shown in FIG. 6, where the spectral line transitions are the same as those in FIG. 4, and the Doppler background is clearly rejected.

The contrasts of PD1 (C_PD1), PD2 (C_PD2) and their difference (C_PD1−C_PD2) as function of relative polarization angle between the linear polarized bichromatic pump and probe light in the single light-atom interaction scheme is plotted in FIG. 7. Here the contrast (C) of the resonance, defined as the ratio between the Lamb-dip (Lamb-peak) signal amplitude and the dc background level in the bottom (top) of the sub-Doppler resonance. The plus (minus) sign of C means a Lamb-peak (Lamb-dip) signal. We can clearly observe in this plot, a Lamb-dip will switch to a Lamb-peak in PD1 as the polarization angle of probe light changed, the same for PD2. The contrast difference (C_PD1−C_PD2) approaches its extremum around +45 degree of relative polarization angle between pump and probe light, this is a unique feature of our application.

Both a single-frequency (monochromatic) or dual-frequency (bichromatic) laser can be locked by the present application.

1) When a monochromatic laser beam is generated, its frequency is f₁. At this time, the quantum resonance system 4 is a degenerate two-level system, as shown in FIG. 3(a), that is, a ground state: |g> and an excited state: |e>, with their eigenfrequency fₑ and f_{g} respectively. The angular momentum associated with the ground (F_{g}) and excited (Fₑ) levels should meet the condition F_{g}≥Fₑ, which makes the simultaneous Lamb-dips and -peaks possible. With the Doppler-free and SNR enhanced differential signals obtained by the present application, the laser frequency is locked onto the transition frequency f_{ge}(=fₑ−f_{g}) of the degenerate two-level quantum resonance system.

2) When a bichromatic laser beam is generated, its frequencies are f₁ and f₂, which interact with a 3-level quantum resonance system, as shown in FIG. 3(b), and couple the two ground states to the co-excited state, i.e., |g₁>→|e> and |g₂>→|e> respectively at the same time. The bichromatic laser beam can be obtained from the multichromatic light output of a semiconductor laser, which is modulated directly by microwave. Two of the sidebands of the output multichromatic light form the bichromatic laser beam, with its frequency spacing being the two ground states splitting, i.e., f_{g12}.

When the microwave frequency is f_{g12}/(2k) (k is a positive integer), the bichromatic laser beam is composed of the +k-order sidebands, and the laser frequency stabilization system of the present application locks the laser carrier (zero-order) frequency in the middle of two resonance transition frequencies of the three-level quantum resonance system, that is, (f_{g1e}+f_{g2e})/2.

When the microwave frequency is f_{g12}/(2k−1) (k is a positive integer), the bichromatic laser beam is composed of the zero-order sideband and the +k (or −k)-order sideband, and the laser frequency stabilization system locks the frequency of the laser carrier to one of the two resonance transition frequencies of the three-level quantum resonance system, that is, f_{g2e}(f_{g1e}).

The advantage of the configuration in which bichromatic laser beams interact with the three-level quantum resonance system are:
1) optical pumping by bichromatic laser can prevent the atomic population from leaking to other ground states, so that the atomic population participating in the light-atom interaction increases;
2) the bichromatic pump light can create CPT dark state with a larger atomic population proportion both in single ground state (Zeeman sublevels) and two ground states, which interacts with the probe light to generate constructive or destructive interference, depending on the relative polarization direction and Raman phase between the pump and probe light, which helps to further increase the contrast of both the Lamb-dip and -peak signals, thus obtaining a differential signal with higher SNR, and realizing a laser frequency stabilization system with even higher frequency stability.

FIG. 2(b) shows a second system configuration of the present application. The second system configuration is similar to the first one, and the difference lies in that an F-P cavity consisting of a first high-reflectivity cavity mirror 3a and a second high-reflectivity cavity mirror 3b is utilized to enable and facilitate the spatial coincidence of the multiple interactions. The F-P cavity used in this scheme can further increase the number of interaction between the laser beam and the quantum resonance system, the huge enhanced efficient optical path length would greatly improving the contrast and SNR of the quantum resonance signal.

FIG. 2(c) shows a third system configuration of the present application. The interaction configuration of the laser beam and the quantum system is similar to that in the first one, and the differences are as follows: 1) the probe light is obtained through the beam splitting of the non-polarizing beam splitter 2, which is beneficial for independently controlling and adjusting the polarization and intensity of the pump light and the probe light, thus simplifying the adjustment of optical setup; 2) the probe light with a certain angle to the polarization direction of the pump light is obtained by adjusting the half-wave plate, and the parallel and vertical polarization components of the probe light are used to obtain a Lamp-dip signal and a Lamp-peak signal respectively, from which a differential signal is obtained at the differential port of a balanced detector; and finally by synchronous modulation and demodulation techniques, a frequency discrimination signal is obtained for the laser frequency locking.

FIG. 2(d) shows a fourth system configuration of the present application. The fourth system is similar to the third one, and the differences are as follows: 1) the spatial positions of the pump light and the probe light are exchanged, and polarization conversion and differential detection are postponed to be behind the non-polarizing beam splitter 2; 2) the pump light, after being modulated by an electro-optic modulator 7, enters the quantum resonance system to have multiple interactions with it, during which four-wave mixing and modulation transfer occur, making the probe light contain a modulated signal after interacting with the quantum resonance system; and through synchronous modulation and demodulation techniques, a frequency discrimination signal can be obtained to realize stabilization of the laser frequency. By combining differential detection of coexisting Lamb-dips and Lamb-peaks with modulation transfer spectroscopy (MTS), the system can obtain a resonance signal with an even higher SNR, thus realizing ultra-high performance laser frequency stabilization.

What is claimed is:

1. A bichromatic laser frequency stabilization method based on differential detection of coexisting Lamb-dips and Lamb-peaks, comprising the steps of:
providing a multichromatic laser beam having frequency component f₁ and f₂ with frequency difference close to the two ground states splitting;
setting the multiple interactions between the laser beam and quantum resonance system in a Doppler-free configuration, in which the laser beam is split into a pump light and a probe light which propagate in opposite directions and overlap in space and act on the quantum resonance system simultaneously;
setting the relative polarization directions of the pump and probe light using wave plate, and setting the relative Raman phases between the pump and probe light using mirrors; this allows the dark state created by the pump light and the two dark states created by the two polarization components of the probe light to have constructive interference and destructive interference respectively, then coexisting Lamb-dips and Lamb-peaks are generated;
separating spatially the transmitted probe light from the pump light, and then separating and detecting the orthogonal polarization components of the probe transmitted light after its interactions with the quantum resonance system, the Lamb-dip signal and Lamb-peak signal are then obtained simultaneously; and
subtracting the Lamb-peak signal from Lamb-dip signal to generate a differential signal.

2. The bichromatic laser frequency stabilization method based on differential detection of coexisting Lamb-dips and Lamb-peaks according to claim 1, wherein:
a monochromatic or a bichromatic laser is locked; when a monochromatic laser with frequency f₁ is desired to be locked, a degenerate two-level quantum resonance system is used; it comprises a ground state |g> and an excited state |e>, with their eigenfrequency fₑ and f_{g} respectively; and the angular momentum associated with F_{g} and excited Fₑ levels meet the condition F_{g}≥Fₑ, which makes the simultaneous Lamb-dips and -peaks possible; with the obtained Doppler-free and SNR enhanced differential signals, the laser frequency is locked to the transition frequency f_{ge} of the degenerate two-level quantum resonance system; when a bichromatic laser is desired to be locked, it couples two ground states to a common excited state in a 3-level quantum resonance system, |g₁> to |e> and |g₂> to |e> respectively, with their transition frequency f_{g1e} and f_{g2e} respectively; the bichromatic laser beam is obtained from the multichromatic light output of a semiconductor laser, which is modulated directly by microwave; when the microwave frequency is f_{g12}/(2k), where the f_{g12} and k are the two ground states splitting and a positive integer respectively, the bichromatic laser beam is composed of the +k-order sidebands, and the laser frequency stabilization system locks the laser carrier frequency in the middle of two res onance transition frequencies of the three-level quantum resonance system; when the microwave frequency is f_{g12}/(2k−1), the bichromatic laser beam is composed of the zero-order sideband and the ±k-order sideband, the laser carrier frequency is locked to one of the two resonance transition frequencies of the three-level quantum resonance system.

3. The bichromatic laser frequency stabilization method based on differential detection of coexisting Lamb-dips and Lamb-peaks according to claim 1, wherein: the quantum resonance system is based on H, Li, Na, K, Rb, Cs, Be, Mg, Ca, Sr, Ba, He, Ne, Ar, Kr, and Xe.

4. A bichromatic laser frequency stabilization system using the method according to claim 1, comprising a multichromatic laser system, a high reflectivity optical device, a quantum resonance system, a space and polarization separation device and balanced detection devices, wherein:
the multichromatic laser system generates a dual-frequency laser beam which then, acting as a pump light, has multiple interactions with the quantum resonance system in a Doppler-free configuration with the help of the high reflectivity optical devices; the transmitted light of the pump beam through the quantum resonance system is converted to a counter-propagated and spatially-overlapped probe light, whose polarization is also adjusted to a proper direction; the probe light enters the quantum resonance system and interacts with it, Lamb-dips and Lamb-peaks are generated corresponding to the two orthogonal polarization components of probe light; a Lamb-dip signal and a Lamb-peak signal are obtained through the space and polarization separation device; the balanced detection devices detect the Lamb-dip signal and the Lamb-peak signal, and the differential signal between the two is also obtained, which is used for the laser frequency locking.

5. The bichromatic laser frequency stabilization system according to claim 4, wherein:
the bichromatic laser beam is generated with direct-modulation a semiconductor laser, in which a microwave signal is coupled to the semiconductor laser through a Bias-Tee; the bichromatic laser beam passes through a non-polarizing beam splitter and then enters the quantum resonance system served as a pump light; a pair of mirrors in the high reflectivity optical devices arranged at two sides of the quantum resonance system, thus the pump light multiple passes the quantum resonance system so as to increase the effective optical path length, which is in favour of higher quantum resonance signal; after the interaction between the pump beam and the quantum resonance system, the transmitted light of the pump beam is reflected as a probe beam, which is overlapped with the pump beam; thanks to a quarter-wave plate, the polarization of probe beam is adjusted to a proper direction relative to the pump beam; the counter-propagated and linear polarized probe light enters the quantum resonance system to interact with it, and the two orthogonal polarization components of the probe light, the parallel polarization component and the vertical polarization component, interact with the quantum resonance system and generate simultaneous Lamb-dips and Lamb-peaks respectively; the transmitted light from the probe light is separated from the pump light through a non-polarizing beam splitter, then passes through a quarter-wave plate and a half-wave plate, its polarization is separated by a polarizing beam splitter; the parallel polarization component is detected by the detection device to obtain a Lamb-dip resonance signal for instance, then the vertical polarization component is detected to obtain a Lamb-peak resonance signal; and finally, a differential signal is obtained by subtracting Lamb-peak signal from Lamb-dip signal.

6. The bichromatic laser frequency stabilization system according to claim 4, wherein:
the high reflectivity optical devices are replaced by an Fabry-Pérot cavity consisting of two cavity mirrors arranged face to face at two sides of the quantum resonance system.

7. The bichromatic laser frequency stabilization system according to claim 4, wherein:
the probe light is obtained from the non-polarizing beam splitter and is configured to be at a certain angle with respect to the polarization direction of the pump light by adjusting the half-wave plate.

8. The bichromatic laser frequency stabilization system according to claim 4, wherein:
the spatial positions of the pump light and the probe light are exchanged, and polarization conversion and differential detection are arranged at the end of the beam splitter; the pump light, after modulation by an electro-optic modulator, enters the quantum resonance system to have multiple interactions with it, during which four-wave mixing and modulation transfer occur, making the probe light contain a modulating signal after interactions with the quantum resonance system; and through synchronous demodulation techniques, a frequency discrimination signal is obtained from the differential signal to stabilize the laser frequency.
